(19) United States
(12) Patent Application Publication
(10) Pub. No.: US 2004/0233645 A1
(43) Pub. Date: Nov. 25, 2004

(54) Portable data storage device

(76) Inventor: Wan-Tien Chen, Taipei (TW)

Correspondence Address: DENNISON, SCHULTZ, DOUGHERTY & MACDONALD, 1727 KING STREET, SUITE 105, ALEXANDRIA, VA, 22314, US

(21) Appl. No.: 10/724,715

(22) Filed: Dec. 2, 2003

(30) Foreign Application Priority Data
May 23, 2003 (TW) 092113941

(51) Int. Cl. H05K 7/20; H05K 1/14

(52) U.S. Cl. 361/737

(57) ABSTRACT

A portable data storage device, in which a first and a second fixing seats can fix a PCB (printed circuit board) and a housing of the storage device. The present invention has the features of being easy for assembling, having a steady housing and having firmness of fixing etc.

### BACKGROUND OF THE INVENTION

1. Field of the Invention

The present invention is related to a portable data storage device, and especially to a portable data storage device comprising a PCB (printed circuit board), a first and a second fixing seat, a housing and a protecting cover; wherein an end of the PCB can fixedly engage the first fixing seat, a connector of the PCB can be fixedly provided thereon with the second fixing seat and is covered with the protecting cover, and the first and the second fixing seats are covered with the housing; thereby the PCB and the housing can be positioned by means of the first and the second fixing seats. The present invention has the features of being easy for assembling, having a steady housing and having firmness of fixing etc.

2. Description of the Prior Art

Conventional portable data storage devices are generally called “portable hard disks”, such a device has a PCB therein, and the PCB is provided thereon with a Flash Memory, and an upper and a lower cover are provided over the outer surfaces thereof. However, the upper and the lower covers have to be assembled concurrently, and be dealt with “supersonic-wave melting”, assembling of them are more difficult, the entire strength of fixing is smaller, and they make inferior aesthetic appearance by having melting lines; moreover, people are accustomed to place such devices in their suitcases or backpacks for carrying with themselves; once the suitcases or backpacks inadvertently drop, the upper and the lower covers of the conventional devices may be broken by collision; such devices thereby are not so ideal.

Additionally, a conventional device generally has its PCB locked on the lower cover with bolts to increase the firmness of fixing. However, after a period of time of using, under the actions of forces of insertion and drawing, the bolts and the PCB tend to form gaps therebetween, then a connector of the PCB may have the phenomenon of loosening during insertion and drawing.

### SUMMARY OF THE INVENTION

The primary object of the present invention is to provide a portable data storage device; the device has the following advantages:

1. The housing of the present invention is integrally formed of metal such as: an extruded aluminum housing; it is more steady, and can avoid breaking that probably be induced by an external force.

2. The housing of the present invention can also be integrally formed by injection of plastic such as: a plastic housing with high strength; it is also more steady, and can avoid breaking that probably be induced by an external force.

3. The device of the present invention does not have a “supersonic-wave” melting line, and thus is more beautiful apparently.

4. The device of the present invention has a housing benefit to integrally forming, a PCB and the housing are firmly engaged with a first and a second fixing seat, the device is easier for assembling, and the entire firmness of fixing thereof is larger.

5. The device of the present invention does not need bolts to assist locking of the PCB; a connector of the PCB does not have the phenomenon of loosening during insertion and drawing.

Technically, the measure that is adopted in the present invention is the development of a portable data storage device, it comprises:

a PCB provided with a circuit, a memory and a connector;

a first fixing seat fixedly engaged with an end of the PCB;

a second fixing seat fixedly engaged with the connector of the PCB;

a housing covers the first and second fixing seats firmly; and

a protecting cover covers the connector firmly; and the housing is a hollow housing integrally formed of metal.

The present invention will be apparent in its features, technical measures and particular functions after reading the detailed description of the preferred embodiments thereof in reference to the accompanying drawings.

### BRIEF DESCRIPTION OF THE DRAWINGS

FIG. 1 is a perspective schematic view of the device of the present invention;

FIG. 2 is an analytic perspective view of the device of the present invention;

FIG. 3 is a sectional schematic view taken from a section line A-A from FIG. 1;

FIG. 4 is a sectional schematic view taken from a section line B-B from FIG. 1;

FIG. 5 is a sectional schematic view taken from a section line C-C from FIG. 1;

FIG. 6 is a perspective schematic view showing another embodiment of the first fixing seat of the present invention;

FIG. 7 is a perspective schematic view of the aforesaid another embodiment of the first fixing seat in FIG. 6;

FIG. 8 is an analytic perspective view of a second embodiment of the present invention.

### DETAILED DESCRIPTION OF THE PREFERRED EMBODIMENT

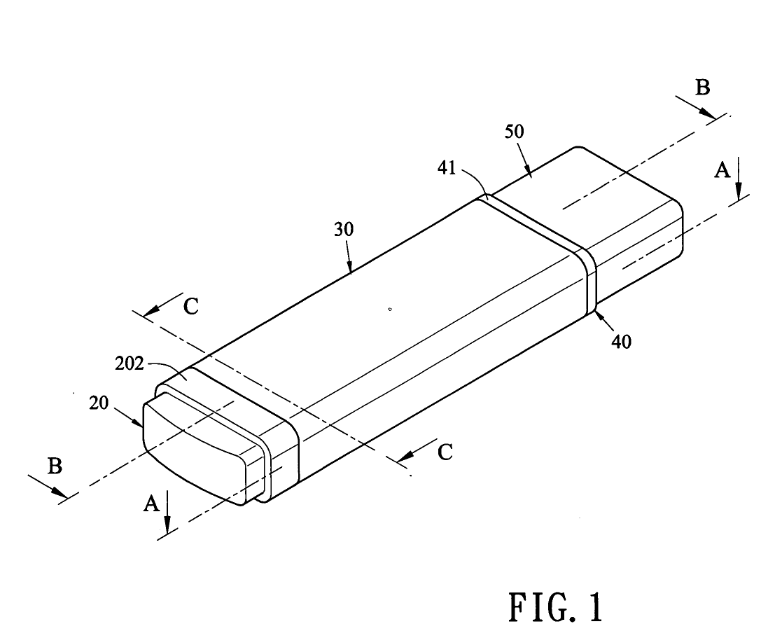

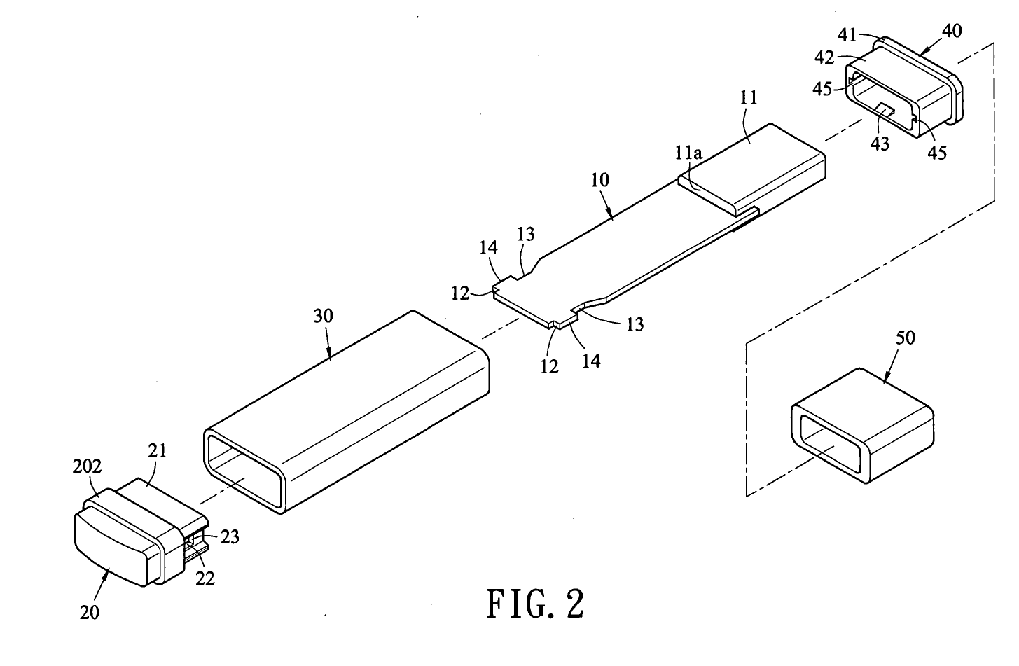

Referring firstly to FIGS. 1 and 2 respectively showing a perspective schematic view and an analytic perspective view of the device of the present invention, as are shown, in the preferred embodiment, the device of the present invention comprises: a PCB 10, a first fixing seat 20, a housing 30, a second fixing seat 40 and a protecting cover 50. Wherein:

The PCB 10 is provided with a connector 11 (such as: a USB connecting plug) on its front end, the tailing end of it is provided with notches 12 and engaging portions 13 respectively on both sides thereof, the notches 12 and engaging portions 13 are formed therebetween wings 14, the PCB 10 is provided also with a circuit and a memory (such as: a Flash Memory); the circuit and the memory are not the objects of the present invention and thereby are not shown in the drawings.

The first fixing seat 20 has therein a receiving space 201, and has a stepped frame 21 provided with positioning holes 22 on both lateral sides thereof for firmly engaging the wings 14 on the tailing end of the PCB 10.

The housing 30 is integrally formed of metal (such as: an extruded aluminum sleeve), or is integrally formed by injection of plastic (such as: a plastic sleeve with high strength), one end of the housing 30 can cover the stepped frame 21 of the first fixing seat 20.

The second fixing seat 40 is a hollow seat provided with a protruding stop portion 41, and has a stepped frame 42 provided with engaging hooks 43 on its upper and lower inner walls for insertion for fixed engaging of the connector 11 of the PCB 10, the front end of the connector 11 can protrude out of the second fixing seat 40. The stepped frame 42 can be slipped in the other end of the housing 30.

The protecting cover 50 covers the connector 11 firmly, and is abutted on the second fixing seat 40.

Thereby a portable data storage device is formed, it can be connected through the connector 11 with a personal computer (PC), a notebook (NB) and some other electronic device for data access at any time, and thereby it has the features of being easy for assembling, having a steady housing and having firmness of fixing etc.

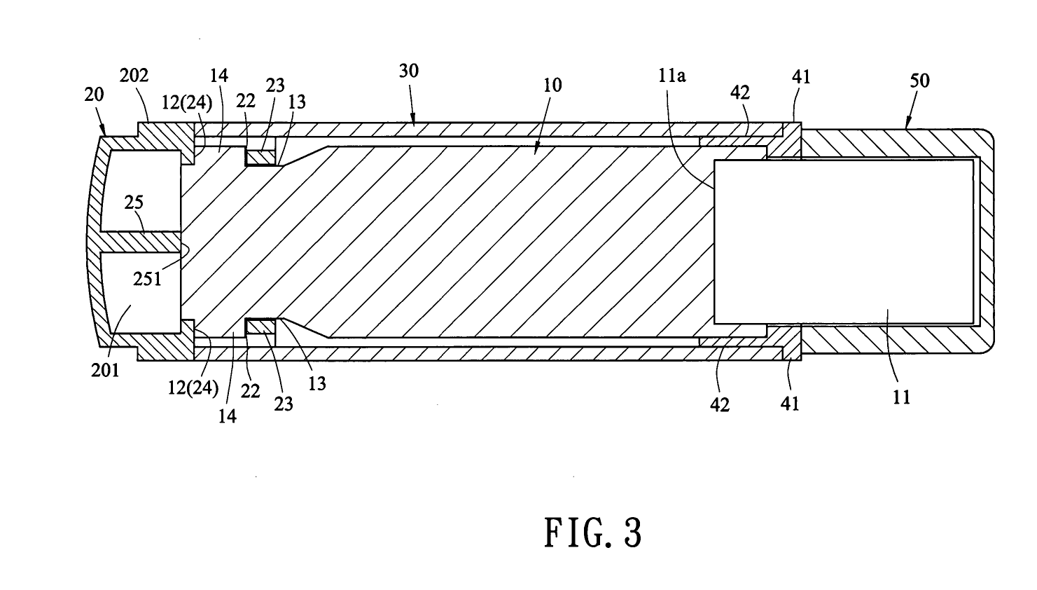

Referring to FIGS. 2 and 3 respectively showing an analytic perspective view of the device of the present invention and a sectional schematic view taken from a section line A-A from FIG. 1, wherein when the first fixing seat 20 is firmly engaged with the tailing end of the PCB 10, the notches 12 of the PCB 10 are abutted on a wall 24 of the first fixing seat 20, the positioning holes 22 provided on the stepped frame 21 are engaged with the wings 14 on the tailing end of the PCB 10, ribs 23 provided at the positioning holes 22 are firmly engaged with the engaging portions 13 on the tailing end of the PCB 10, thereby firmness of fixing of the second fixing seat 40 and the PCB 10 can be largely increased.

Besides, the housing 30 can be abutted against by two stop portions 202, 41 respectively of the first fixing seat 20 and the second fixing seat 40, hence the second fixing seat 40 can further be provided with slits 45 on two inner lateral sides of the stepped frame 42 for firm engagement of the front end of the PCB 10.

The above stated structural features and the space style constructed form the quintessence of the device of the present invention.

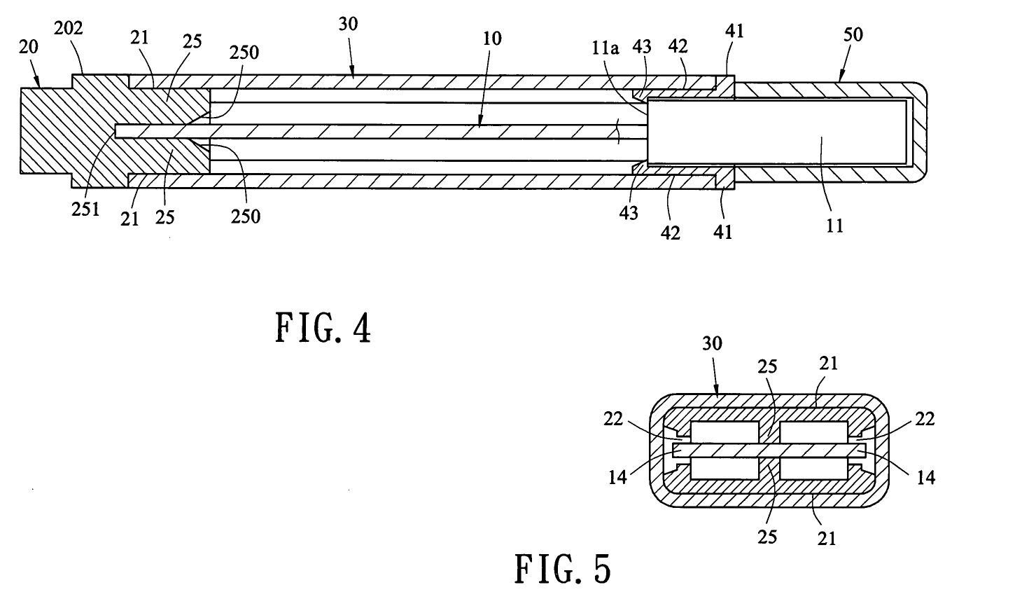

Referring to FIGS. 4-6 respectively showing a sectional schematic view taken from a section lines B-B, C-C of FIG. 1 and a perspective schematic view showing another embodiment of the first fixing seat of the present invention, wherein the first fixing seat 20 can further be provided with supporting portions 25 respectively on the inner upper and lower walls of the stepped frame 21 for engagement of the tailing end of the PCB 10 to fixedly clamp the end of the PCB 10.

And the two engaging hooks 43 of the second fixing seat 40 can firmly engage an end 11a of the connector 11 in order to prevent retracting or loosening of the PCB 10 during insertion and drawing.

And more, when the first fixing seat 20 engages with the end of the PCB 10, the PCB 10 can be tightly abutted against a stop wall 251 provided between the two supporting portions 25.

The supporting portions 25 each can be further provided with a declined surface 250 in favor of leading in the tailing end of the PCB 10 to make easier assembling of the first fixing seat 20 and the PCB 10.

The above stated structural features can increase the entire firmness of fixing without bolts to assist locking of the PCB; and they can make the connector 11 of the PCB not subjected to having the phenomenon of loosening during insertion and drawing. This can be deemed as a broadening of the scope of the preferred embodiment of the device of the present invention, it is not departed from the spirit of the present invention, and thereby shall fall into the scope of the present invention.

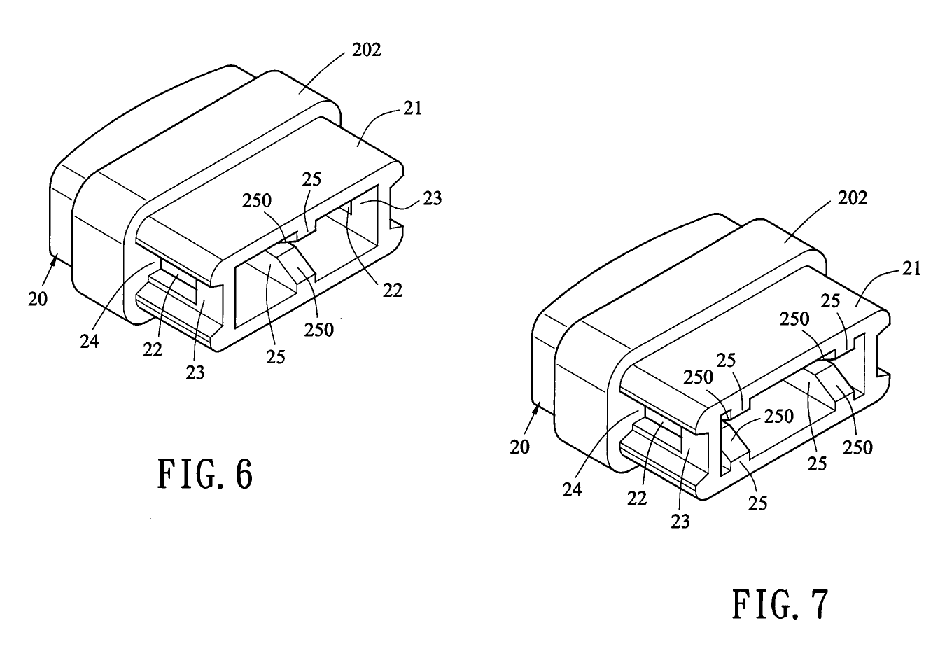

As shown in FIG. 7 that is a perspective schematic view of the aforesaid another embodiment of the first fixing seat in FIG. 6, wherein the first fixing seat 20 is provided with two pair of supporting portions 25 respectively on the inner upper and lower walls of the stepped frame 21, these pairs of supporting portions 25 are spaced away mutually for a suitable distance, this is for the purpose of adding an related electronic element on the tailing end of the PCB 10.

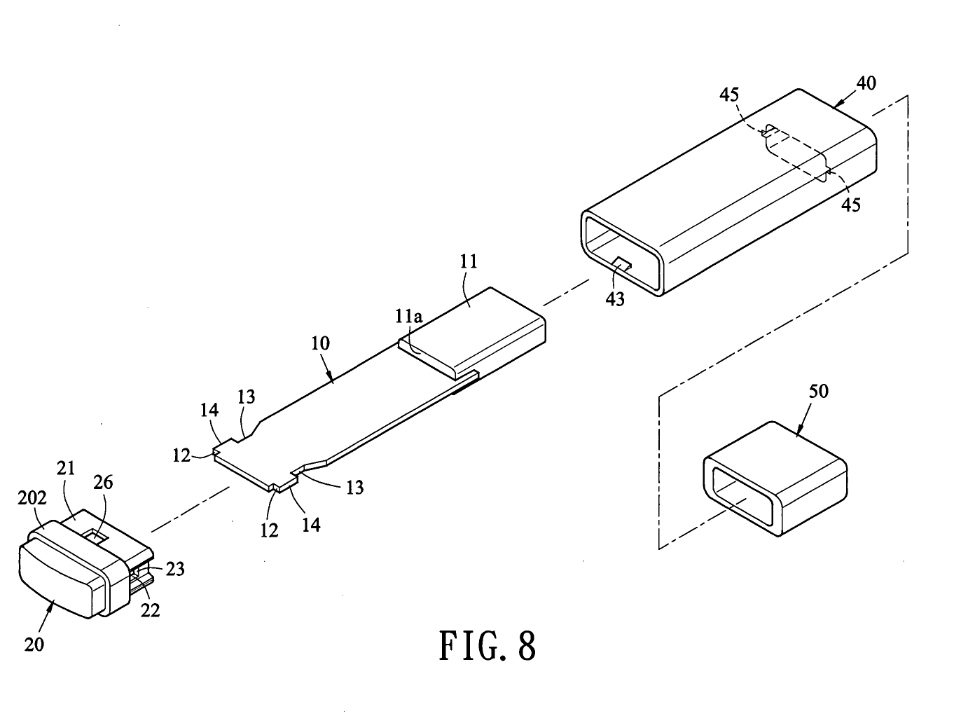

Referring to FIG. 8 that is an analytic perspective view of a second embodiment of the present invention, as is shown, in the second embodiment, the device of the present invention does not have a housing 30, but still has a PCB 10, a first fixing seat 20, a second fixing seat 40 and a protecting cover 50. Wherein:

The first fixing seat 20 is provided therein with a receiving space 201, and has a stepped frame 21 provided with first positioning holes 22 respectively on both lateral sides thereof for firmly engaging wings 14 on the tailing end of the PCB 10. Ribs 23 are provided at the first positioning holes 22 and are firmly engaged with engaging portions 13 on the tailing end of the PCB 10. The stepped frame 21 is further provided with second positioning holes 26 on the top and bottom surfaces thereof.

The second fixing seat 40 is a hollow seat integrally formed by injection of plastic (such as: a plastic sleeve with high strength) for insertion and fixed engaging of a connector 11 of the PCB 10; the front end of the connector 11 can protrude out of the second fixing seat 40. The second fixing seat 40 has engaging hooks 43 respectively on its upper and lower inner walls for fixed engaging in the second positioning holes 26 of the first fixing seat 20.

And the second fixing seat 40 can further be provided with slits 45 respectively on two inner lateral sides of the stepped frame 42 for firm engagement of the front end of the PCB 10, thereby firmness of fixing of the second fixing seat 40 and the PCB 10 can be largely increased.

The above stated second embodiment is also a practical device of the present invention, it can be deemed as broadening of the scope of the first preferred embodiment of the device of the present invention, it is not departed from the spirit of the present invention, and thereby shall fall into the scope of the present invention.

Conclusively, having thus described the technical process of my invention, there has been no product of such structural features in the markets, what I claim as new and desire to be secured by Letters Patent of the United States are:

1. A portable data storage device comprising:
a PCB (printed circuit board), a first fixing seat, a housing, a second fixing seat and a protecting cover, wherein:
said PCB is provided with a connector on a front end thereof, and is respectively provided with wings and engaging portions on both sides of a tailing end thereof, said PCB is provided also with a circuit and a memory;
said first fixing seat has therein a receiving space, and has a stepped frame respectively provided with positioning holes on both lateral sides thereof for firmly engaging said wings on said tailing end said the PCB; ribs are provided at said positioning holes and are engaged with engaging portions on said tailing end of said PCB;
said housing is integrally formed of metal, one end of said housing is adapted for covering said stepped frame of said first fixing seat;
said second fixing seat is a hollow seat provided with a protruding stop portion, and has another stepped frame provided with engaging hooks on an upper inner wall thereof for insertion for fixed engaging of said connector of said PCB, a front end of said connector protrudes out of said second fixing seat, said stepped frame is slipped in the other end of said housing;
said protecting cover covers said connector firmly, and is abutted on said second fixing seat;
thereby said portable data storage device is formed, and has features of being easy for assembling, having said steady housing and having firmness of fixing.

2. The portable data storage device as in claim 1, wherein:
said connector is a USB connecting plug, said memory is a Flash Memory.

3. The portable data storage device as in claim 1, wherein:
said housing is an extruded aluminum housing.

4. The portable data storage device as in claim 1, wherein:
said housing is a hollow housing integrally formed by injection of plastic with high strength.

5. The portable data storage device as in claim 1, wherein:
said second fixing seat has engaging hooks on a lower inner wall of said stepped frame provided on said second fixing seat.

6. The portable data storage device as in claim 1, wherein:
said first fixing seat has a wall on said protruding stop portion, said tailing end of said PCB is provided further with notches; when said first fixing seat is firmly engaged with said tailing end of said PCB, said notches of said PCB are abutted on said wall of said first fixing seat, said positioning holes provided on said first fixing seat are engaged with said wings on said tailing end of said PCB, said ribs of said first fixing seat are firmly engaged with said engaging portions on said tailing end of said PCB.

7. The portable data storage device as in claim 1, wherein:
said second fixing seat is provided with slits on two inner lateral sides of said stepped frame of said second fixing seat for firm engagement of said front end of said PCB.

8. The portable data storage device as in claim 1, wherein:
said first fixing seat is further provided with two supporting portions respectively on an inner upper and a lower wall of said stepped frame of said first fixing seat for engagement of said tailing end of said PCB to fixedly clamp said end of said PCB.

9. The portable data storage device as in claim 8, wherein:
a stop wall is provided between said two supporting portions, said tailing end of said PCB is tightly abutted against said stop wall; said supporting portions each is further provided with a declined surface in favor of leading in said tailing end of said PCB.

10. The portable data storage device as in claim 1, wherein:
said first fixing seat is further provided with two supporting portions respectively on an inner upper and a lower wall of said stepped frame of said first fixing seat, said supporting portions are spaced away mutually for a predetermined distance for the purpose of adding an related electronic element on said tailing end of said PCB.

11. A portable data storage device comprising:
a PCB, a first fixing seat, a second fixing seat and a protecting cover, wherein:
said PCB is provided with a connector on a front end thereof, and is provided with wings and engaging portions respectively on both sides of a tailing end thereof, said PCB is provided also with a circuit and a memory;
said first fixing seat has therein a receiving space, and has a stepped frame provided with first positioning holes respectively on both lateral sides thereof for firmly engaging said wings on said tailing end of said PCB; ribs are provided at said first positioning holes and are firmly engaged with engaging portions on said tailing end of said PCB, said stepped frame of said first fixing seat is further provided with second positioning holes respectively on top and bottom surfaces thereof;
said second fixing seat is a hollow seat integrally formed by injection of plastic for insertion and fixed engaging of a connector of said PCB;
a front end of said connector protrudes out of said second fixing seat, said second fixing seat has engaging hooks respectively on an upper and a lower inner wall thereof for fixed engaging in said second positioning holes of said first fixing seat;
said protecting cover covers said connector firmly, and is abutted on said second fixing seat;
thereby said portable data storage device is formed, and has features of being easy for assembling, having said steady housing and having firmness of fixing.

12. The portable data storage device as in claim 11, wherein:
said connector is a USB connecting plug, said memory is a Flash Memory.

13. The portable data storage device as in claim 11, wherein:
said second fixing seat is a plastic sleeve with high strength.

14. The portable data storage device as in claim 11, wherein:
said first fixing seat has a wall on said protruding stop portion, said tailing end of said PCB is provided further with notches; when said first fixing seat is firmly engaged with said tailing end of said PCB, said notches of said PCB are abutted on said wall of said first fixing seat, said positioning holes provided on said first fixing seat are engaged with said wings on said tailing end of said PCB, said ribs of said first fixing seat are firmly engaged with said engaging portions on said tailing end of said PCB.

15. The portable data storage device as in claim 11, wherein:
said second fixing seat is provided with slits respectively on two inner lateral sides of said stepped frame of said second fixing seat for firm engagement of said front end of said PCB.

16. The portable data storage device as in claim 11, wherein:
said first fixing seat is further provided with two supporting portions respectively on upper and lower inner walls of said stepped frame of said first fixing seat for engagement of said tailing end of said PCB to fixedly clamp said end of said PCB.

17. The portable data storage device as in claim 16, wherein:
a stop wall is provided between said two supporting portions, said tailing end of said PCB is tightly abutted against said stop wall; said supporting portions each is further provided with a declined surface in favor of leading in said tailing end of said PCB.

18. The portable data storage device as in claim 11, wherein:
said first fixing seat is further provided with two supporting portions respectively on upper and lower inner walls of said stepped frame of said first fixing seat, said supporting portions are spaced away mutually for a predetermined distance for the purpose of adding an related electronic element on said tailing end of said PCB.
